(19) United States
(12) Patent Application Publication
(10) Pub. No.: US 2001/0013802 A1
(43) Pub. Date: Aug. 16, 2001

(54) SYSTEM AND PROCESS FOR HIGH SPEED INTERFACE CLOCK SKEW CORRECTION

(76) Inventors: GHENE FAULCON, REDONDO BEACH, CA (US); MATTHEW SCOTT MCGREGOR, HUNTINGTON BEACH, CA (US); RUSSELL SCOTT DICKERSON, HERMOSA BEACH, CA (US)

Correspondence Address: TED R. RITTMASTER, ESQ., FOLEY & LARDNER, 2029 CENTURY PARK EAST, SUITE 3500, LOS ANGELES, CA, 90067-3021, US

(21) Appl. No.: 09/348,519

(22) Filed: Jul. 7, 1999

(51) Int. Cl. H03L 7/06

(52) U.S. Cl. 327/244

(57) ABSTRACT

A receiving system for aligning a first signal to a reference signal is disclosed. In the receiving system, a selectable delay receives a first signal and delays the first signal by a selectable amount to generate a delayed first signal. A phase detector receives the delayed first signal and a reference signal and generates phase information which represents a phase difference between the delayed first signal and the reference signal. A phase accumulator receives and accumulates the phase information and generates delay select information which represents an accumulated phase difference between the delayed first signal and the reference signal. The selectable delay receives the delay select information and delays the first signal based on the delay select information, resulting in improved alignment of the delayed first signal and the reference signal. The receiving system may also include a second delay for receiving a second signal and delaying it by a fixed amount to generate the reference signal.

### BACKGROUND OF THE INVENTION

1. Field of the Invention

The present invention relates, generally, to systems and processes which transmit and receive data, and, in particular embodiments, to receiving systems and processes for aligning transmitted data and clock signals to minimize clock skew and data transmission errors.

2. Description of Related Art

Modern electronic systems often utilize synchronous data transfer, wherein digital data signals are interpreted in conjunction with a corresponding clock signal. Synchronous data interfaces are desirable because the data is not sampled until a clock edge is present, which provides a measure of immunity against switching and other high frequency noise generated by high-speed digital electronics. Typically, the clock edge used to sample or “clock” a data signal is designed to occur during a period when noise on the data signal is at a minimum. Thus, related data and clock signals are commonly transmitted from one functional block to another across circuit board traces, backplanes, wires, and the like.

As data and clock signals travel across such interfaces, their timing and waveshapes are affected by the physical characteristics of the interface. Distributed capacitances, impedance mismatches, signal reflections, and the like are, at least partially, a function of the length of the interface, and can have a significant effect on the timing and shape of the transmitted signals. When the transmission distance is small, these effects are often minimal and the timing relationship between data and clock may be insignificantly affected. However, as the transmission distance increases, these effects may increase. When the interface is not perfectly matched, two simultaneously transmitted signals may arrive at receiving circuitry with a delay between them. This delay is proportional to the difference in the electrical lengths of the conductors in the electrical interface.

Without any compensation techniques, digital systems can tolerate delays of about one-quarter of a clock period or more. For systems with “slow” clocks (less than one gigahertz (GHz)), the resulting delays may not cause a problem for the receiving system. However, in systems with “high-speed” clocks (greater than one GHz), the delay may be large enough to cause data errors.

A receiving system capable of tolerating or compensating for these delays would minimize the data errors associated with mismatched electrical interfaces. Previous methods of aligning clock and data such as U.S. Pat. No. 5,652,530 have involved shifting the clock signal to align it with the data signal. In a system in which the clock and data phase error varies, the resulting dynamic adjustments to the clock can have significant effects on the system receiving the adjusted clock and data, including loss of synchronization for external phase locked loops (PLLs). Other correction methods have used PLLs to control the phase relationship between the clock and the data. These methods require a frequency source whose frequency is an integer multiple of the clock being phase-corrected. In systems with high-speed clocks, generating higher clock frequencies for the PLL can be expensive and/or impractical. These higher multiple clocks are also more difficult to employ in a practical design, because high-speed signals are more susceptible to the bandwidth limitations of cables and printed circuit board (PCB) traces, and are more sensitive to reflections and parasitic effects.

Other approaches introduce fixed delays to compensate for clock skew. These approaches do not introduce problems as a result of dynamic changes to the clock, but such systems cannot account for variable changes in phase error due to temperature, humidity, and other external influences.

### SUMMARY OF THE DISCLOSURE

Therefore, it is an advantage of embodiments of the present invention to provide a system and process for aligning transmitted data and clock signals to minimize clock skew and data transmission errors.

It is a further advantage of embodiments of the present invention to provide a system and process for aligning transmitted data and clock signals that dynamically changes the phase relationship of the data signal with respect to the clock signal, but does not change the frequency of the clock signal.

It is a further advantage of embodiments of the present invention to provide a system and process for aligning transmitted data and clock signals that does not need an additional frequency source.

It is a further advantage of embodiments of the present invention to provide a system and process for aligning transmitted data and clock signals that can self-correct to compensate for single-event upsets (SEUs) in the receiving system.

It is a further advantage of embodiments of the present invention to provide a system and process for aligning two or more signals of a variety of types, for example two or more clock signals, burst clocks, data signals, or combinations thereof.

These and other objects are accomplished according to a receiving system for aligning a first signal to a reference signal. In the receiving system, a selectable delay receives a first signal and delays the first signal by a selectable amount to generate a delayed first signal. A phase detector receives the delayed first signal and a reference signal and generates phase information which represents a phase difference between the delayed first signal and the reference signal. A phase accumulator receives and accumulates the phase information and generates delay select information which represents an accumulated phase difference between the delayed first signal and the reference signal. The selectable delay receives the delay select information and delays the first signal based on the delay select information, resulting in improved alignment of the delayed first signal and the reference signal. The receiving system may also include a second delay for receiving a second signal and delaying it by a fixed amount to generate the reference signal.

These and other objects, features, and advantages of embodiments of the invention will be apparent to those skilled in the art from the following detailed description of embodiments of the invention, when read with the drawings and appended claims.

### BRIEF DESCRIPTION OF THE DRAWINGS

FIG. 1 is block diagram representation of a phase alignment system according to an example embodiment of the present invention.

FIG. 2 is a block diagram representation of an embodiment of the fixed clock delay shown in FIG. 1.

FIG. 3 is a block diagram representation of the phase detector in the system of FIG. 1.

FIG. 4 is a logic diagram representation of an embodiment of the phase detector shown in FIG. 3.

FIG. 5 is a logic diagram representation of an embodiment of the phase accumulator shown in FIG. 1.

FIG. 6 is a block diagram representation of the selectable delay in the system of FIG. 1.

FIG. 7 is a more detailed block diagram representation of an embodiment of the selectable delay shown in FIG. 6.

FIG. 8 is a logic diagram representation of an alternative embodiment of the fixed clock delay shown in FIG. 1.

FIG. 9 is a logic diagram representation of an alternative embodiment of the phase detector shown in FIG. 3.

FIG. 10 is a logic diagram representation of an alternative embodiment of the phase accumulator shown in FIG. 1.

FIG. 11 is a logic diagram representation of an alternative embodiment of the selectable delay shown in FIG. 6.

FIG. 12 is block diagram representation of a system environment according to an alternative example embodiment of the present invention.

FIG. 13 is logic diagram representation of an embodiment of the system environment shown in FIG. 12.

### DETAILED DESCRIPTION OF PREFERRED EMBODIMENTS

In the following description of preferred embodiments, reference is made to the accompanying drawings which form a part hereof, and in which is shown by way of illustration specific embodiments in which the invention may be practiced. It is to be understood that other embodiments may be utilized and structural changes may be made without departing from the scope of the preferred embodiments of the present invention.

Modern electronic systems often utilize synchronous data transfer, wherein digital data signals are interpreted in conjunction with a corresponding clock signal. Thus, data and clock signals are commonly transmitted from one functional block to another across circuit board traces, backplanes, wires, or the like. As data and clock signals travel across such interfaces, their timing and waveshapes are affected by the physical characteristics of the interface. When the interface is not perfectly matched in electrical length, two simultaneously transmitted clock and data signals may arrive at receiving circuitry with a delay between them. This delay is proportional to the difference in the electrical lengths of the conductors in the electrical interface. In systems with high-speed clocks, the delay may be large enough to cause data interpretation errors. A receiving system capable of tolerating or compensating for these delays would minimize the data errors associated with mismatched electrical interfaces.

Embodiments of the present invention therefore relate to receiving systems and processes for aligning transmitted data and clock signals to minimize clock skew and data transmission errors. It should be noted, however, that receiving systems according to embodiments of the present invention are not limited to clock and data pairs, but may be used to align two or more signals of a variety of types, for example two or more clock signals, burst clocks, data signals, or combinations thereof. However, for purposes of simplifying the present disclosure, preferred embodiments of the present invention are described herein in relation to the transmission of first and second signals composed of a data signal and a corresponding clock signal, respectively.

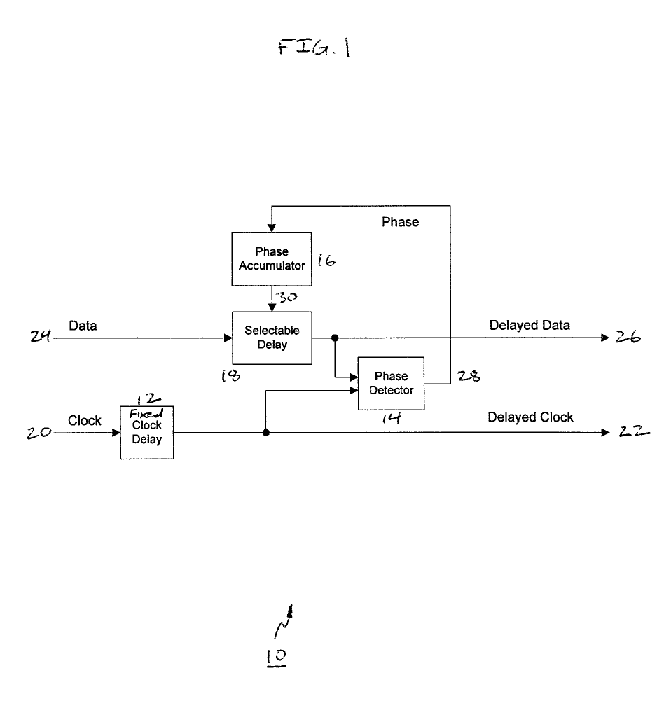

A generalized representation of a receiving system according to an embodiment of the present invention is shown in FIG. 1, where a receiving system 10 includes a clock delay 12, a phase detector 14, a phase accumulator 16, and a selectable delay 18. Clock delay 12 receives a clock signal 20 and delays it by a fixed amount, producing a delayed clock signal 22. In preferred embodiments, clock delay 12 delays clock signal 20 by an amount approximately equivalent to one half of the maximum delay achievable through selectable delay 18. Selectable delay 18 receives a data signal 24 and delays it by a selectable amount to produce a delayed data signal 26. Phase detector 14 receives delayed clock signal 22 and delayed data signal 26 and produces phase information 28 that varies according to the phase relationship of delayed data signal 26 relative to delayed clock signal 22. Phase accumulator 16 receives and accumulates phase information 28, producing delay select information 30. Selectable delay 18 receives delay select information 30 and adjustably delays data signal 24 based on delay select information 30.

Receiving system 10 continuously corrects the phase relationship between delayed data and clock signals 26 and 22 until the phase difference between delayed data and clock signals 26 and 22 is minimized. If delayed data and clock signals 26 and 22 drift after this equilibrium has been established, phase detector 14 will detect the phase difference and adjust accordingly. In this sense, the receiving system behaves in a manner similar to a PLL. Unlike a PLL, however, there is no higher frequency clock used for synchronization.

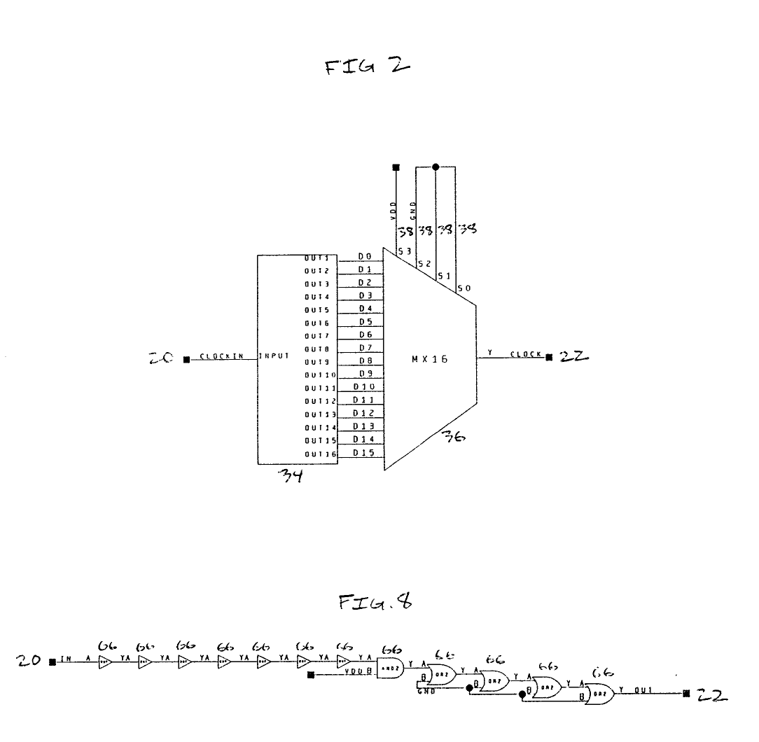

FIGS. 2-7 represent preferred embodiments of components of the receiving system shown in FIG. 1. FIG. 2 is a block diagram representation of an embodiment of a clock delay 12 shown in the system of FIG. 1, and illustrates a fixed clock delay created by using an incremental delay generator 34 and a 16-to-1 multiplexer 36, with multiplexer inputs 38 set to a fixed state. The fixed clock delay produced by incremental delay generator 34 and multiplexer 36 delays clock signal 20 by an amount approximately equivalent to one half of the maximum delay achievable through selectable delay 18 (see FIG. 1). Although incremental delay generator 34 and multiplexer 36 are not needed from a logic perspective, these elements are used to match those elements found in the delay path of data signal 24 within selectable delay 18, as illustrated in FIG. 7. Additionally, the logic elements of incremental delay generator 34 and multiplexer 36 are preferably fabricated from the same semiconducting material, at the same time, and using the same processing techniques as the logic elements found in selectable delay 18 of FIG. 7. By closely or identically matching design and fabrication, the fixed clock delay can closely approximate one half of the maximum delay achievable through selectable delay 18. It should be noted that clock delay 12 of FIG. 1 is not essential to the operation of receiving system 10, but in preferred embodiments, it helps to speed up clock and data synchronization at start-up.

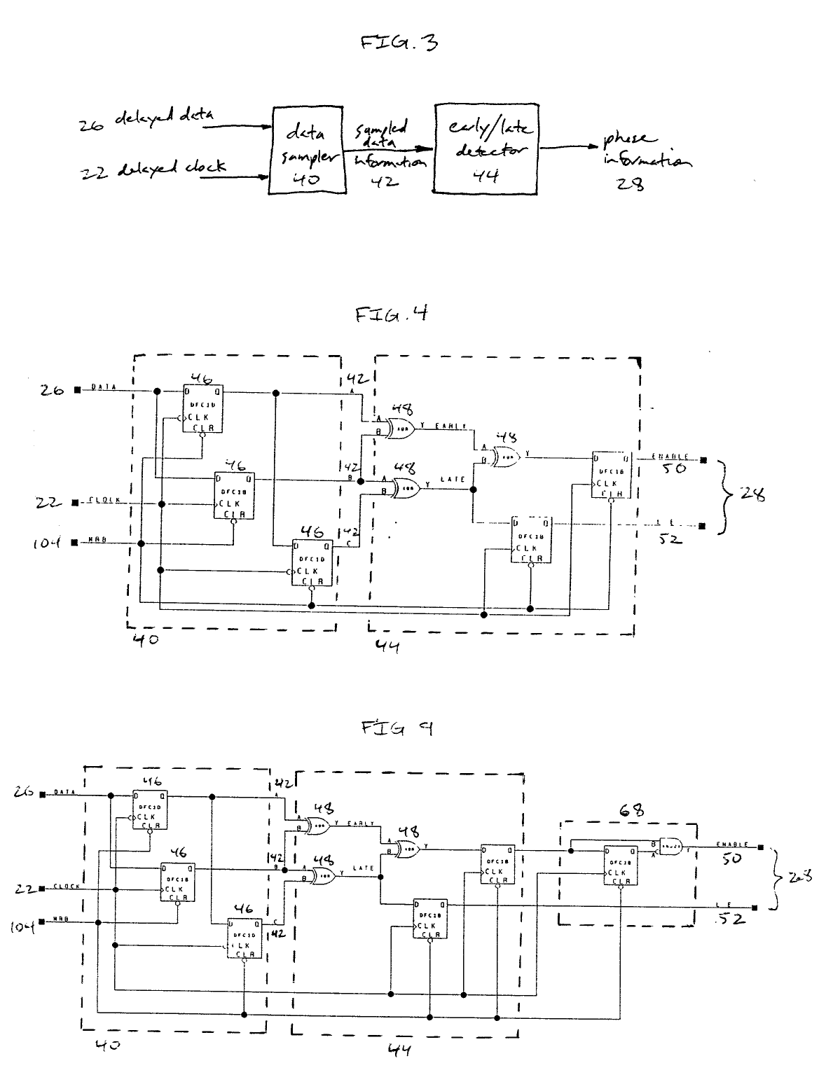

FIG. 3 is a block diagram representation of phase detector 14 in the system of FIG. 1, where a data sampler 40 receives delayed clock and data signals 22 and 26 and samples delayed data signal 26 with respect to delayed clock signal 26, producing sampled data information 42. Sampled data information 42 is then received by an early/late detector 44, which produces phase information 28 representing the phase relationship of the delayed data and clock signals 26 and 22. The memory elements within early/late detector 44 serve the additional function of reducing the probability that any metastability in the memory elements of data sampler 40 will be seen by phase accumulator 16.

FIG. 4 is a logic diagram representation of a preferred embodiment of the data sampler 40 and early/late detector 44 shown in FIG. 3. Data sampler 40 includes memory elements 46 for sampling delayed data signal 26 at consecutive falling, rising, and falling edges of delayed clock signal 22, and produces the outputs of memory elements 46 as sampled data information 42. Early/late detector 44 receives sampled data information 42, uses exclusive-OR gates 48 to detect whether a transition on delayed data signal 26 is early, late, unknown, or nonexistent with respect to a falling edge of delayed clock signal 22, and communicates this result as phase information 28. Phase information 28 includes late/early signal 52, which indicates whether delayed data signal 26 is early or late with respect to delayed clock signal 22, and enable signal 50, which indicates when late/early signal 52 is valid.

FIG. 5 is a logic diagram representation of phase accumulator 16 in the system of FIG. 1, where enable logic 54 receives late/early signal 52, enable signal 50, and delay select information 30, and utilizes logic gates 56 to enable an up/down counter 58 when enable signal 50 is received, except when up/down counter 58 is already at its maximum or minimum count. Up/down counter 58 counts up when up/down counter enable 60 is asserted and late/early signal 52 is “late,” and counts down when up/down counter enable 60 is asserted and late/early signal 52 is “early.” An output of early/late counter 54 is delay select information 30, which indicates the particular delay to be coupled into the data path within selectable delay 18.

In preferred embodiments of the present invention, up/down counter 58 is initially preset to a particular value to produce a delay in the data path that corresponds to the fixed delay in clock delay 12. In other preferred embodiments, only the most significant bits (MSBs) of up/down counter 58 are included in delay select information 30. By not using the least significant bits (LSBs), several enabled late/early signals 52 are required before a data delay adjustment is made, slowing the phase change rate and minimizing metastability from phase detector 14.

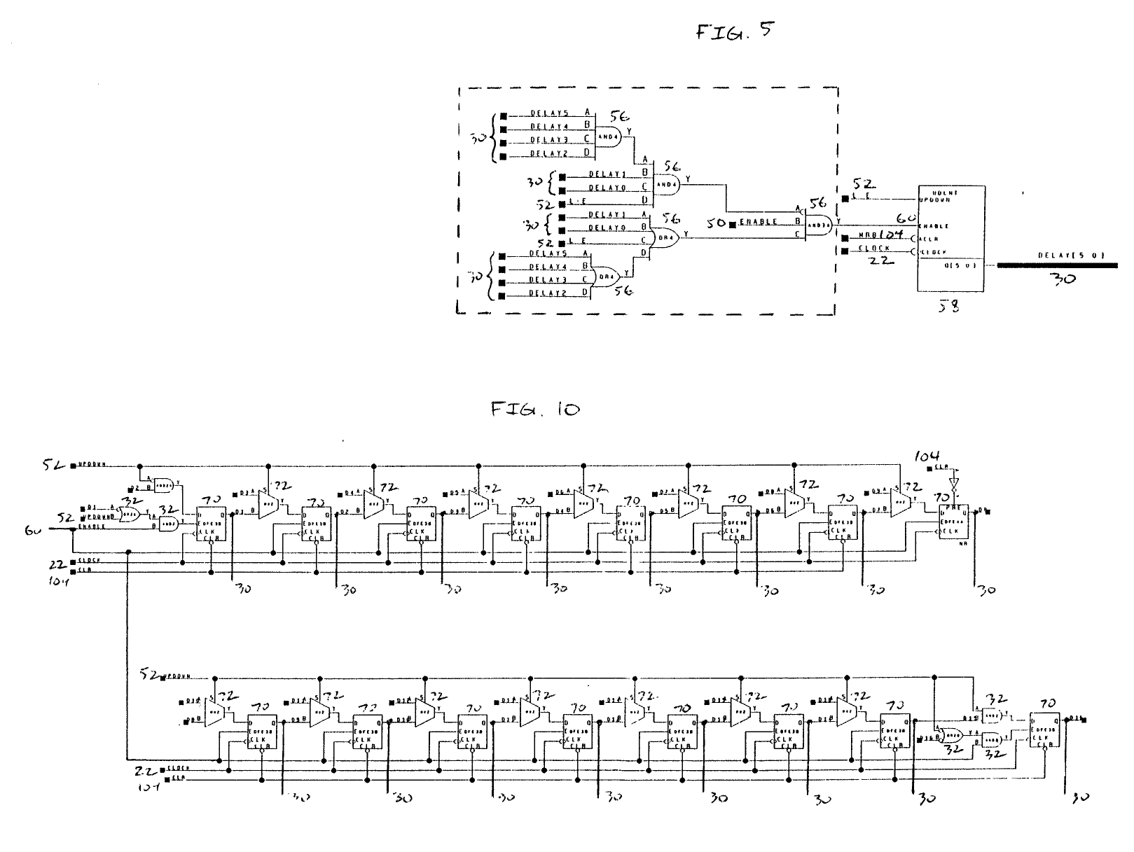

FIG. 6 is a block diagram representation of selectable delay 18 in the system of FIG. 1, where an incremental delay generator 60 receives data signal 24 and produces a plurality of incremental delays 62, each incremental delay 62 representing data signal 24 delayed by a successively increasing amount. The plurality of incremental delays 62 is received by delay selector 64, which channels a particular incremental delay 62 through to delayed data signal 26 based on the state of delay select information 30. FIG. 7 is a more detailed block diagram representation of a preferred embodiment of selectable delay 18 for use with the embodiment of phase accumulator 16 illustrated in FIG. 5, where delay selector 64 is a multiplexer.

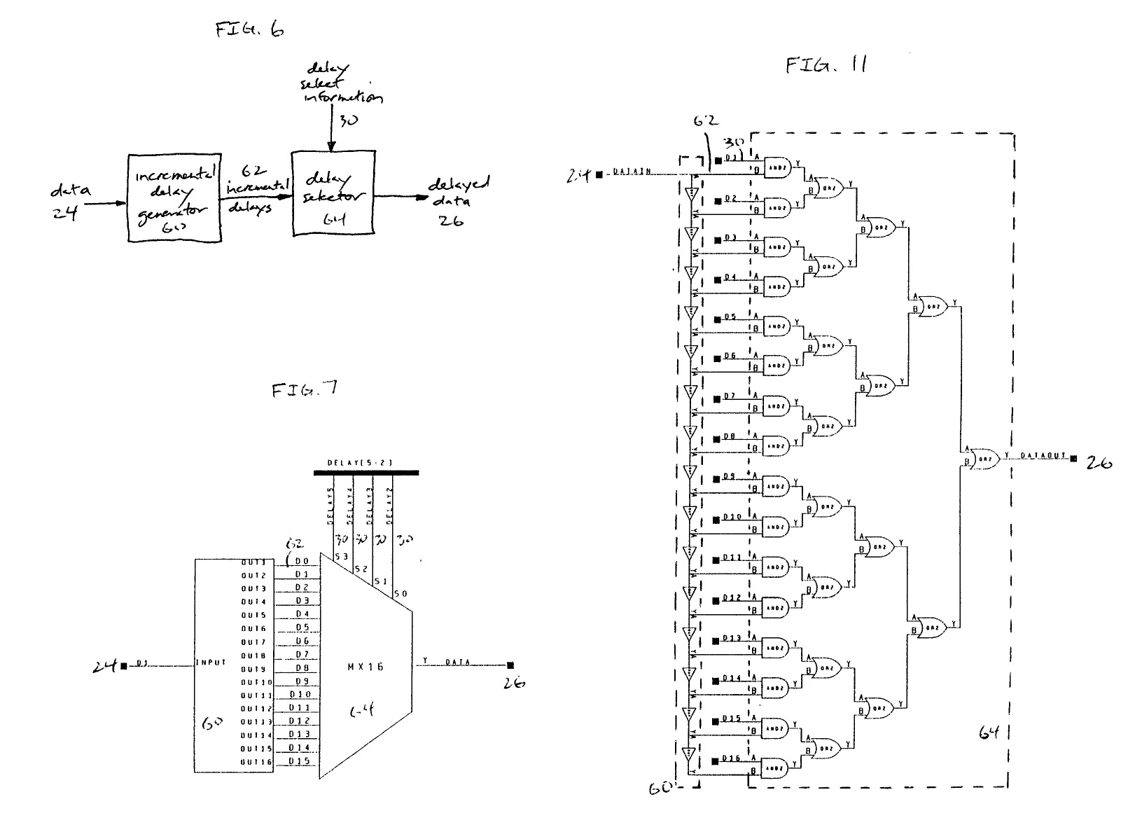

FIGS. 8-11 represent an alternative embodiment of the receiving system shown in FIG. 1. FIG. 8 is a logic diagram representation of clock delay 12 in the system of FIG. 1, and is another example of the delay path matching described above with reference to FIG. 2. FIG. 8 illustrates a fixed delay created by using a series of logic gates 66 that are not needed from a logic perspective, but are chosen to match those elements found in the delay path of data signal 24 within selectable delay 18, as illustrated in FIG. 11.

FIG. 9 is a logic diagram representation of an alternative embodiment of phase detector 14 shown in FIG. 3, and is identical to the preferred embodiment of FIG. 4, except that a pulse generator 68 is added to limit the enable signal 50 to a pulse one clock period wide. Pulse generator 68 prevents the occurrence of several enabled late/early signals 52 at consecutive clock periods, which slows the phase change rate and minimizes metastability from phase detector 14.

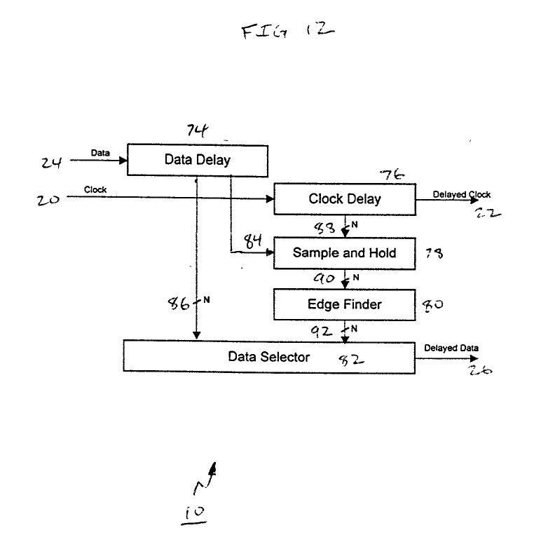

FIG. 10 is a logic diagram representation of phase accumulator 16 in the system of FIG. 1. In FIG. 1, memory elements 70 are configured as a shift register and are controlled by memory element multiplexers 72 to shift either left or right based on late/early signal 52, when enabled by enable signal 60. All memory elements 70 except one are initially preset to one state (a logic “0” in the example of FIG. 10), with the remaining memory element 70 preset to an opposite state (a logic “1” in the example of FIG. 10). The location of the memory element set to logic “1” then shifts left or right according to late/early signal 52. However, if the logic “1” location shifts to the leftmost or rightmost memory element 70, disable logic elements 32 prevent further shifting left or right. The outputs of the shift register form delay select information 30, which controls the particular delay to be coupled into the data delay path within selectable delay 18. It should be noted that in preferred embodiments of the present invention, the logic “1” is preset into the particular memory element 70 that will produce a delay in the data path corresponding to the fixed delay in clock delay 12.

FIG. 11 is a logic diagram representation of an alternative embodiment of selectable delay 18 shown in FIG. 6. In FIG. 6, each incremental delay 62 from incremental delay generator 60 is gated to correspond with an individual output of delay select information 30, which also corresponds to an individual output of memory elements 70 shown in FIG. 10. In the example of FIG. 10, the memory element 70 whose output is at logic “1” causes the corresponding incremental delay 62 to be gated through to delayed data signal 26.

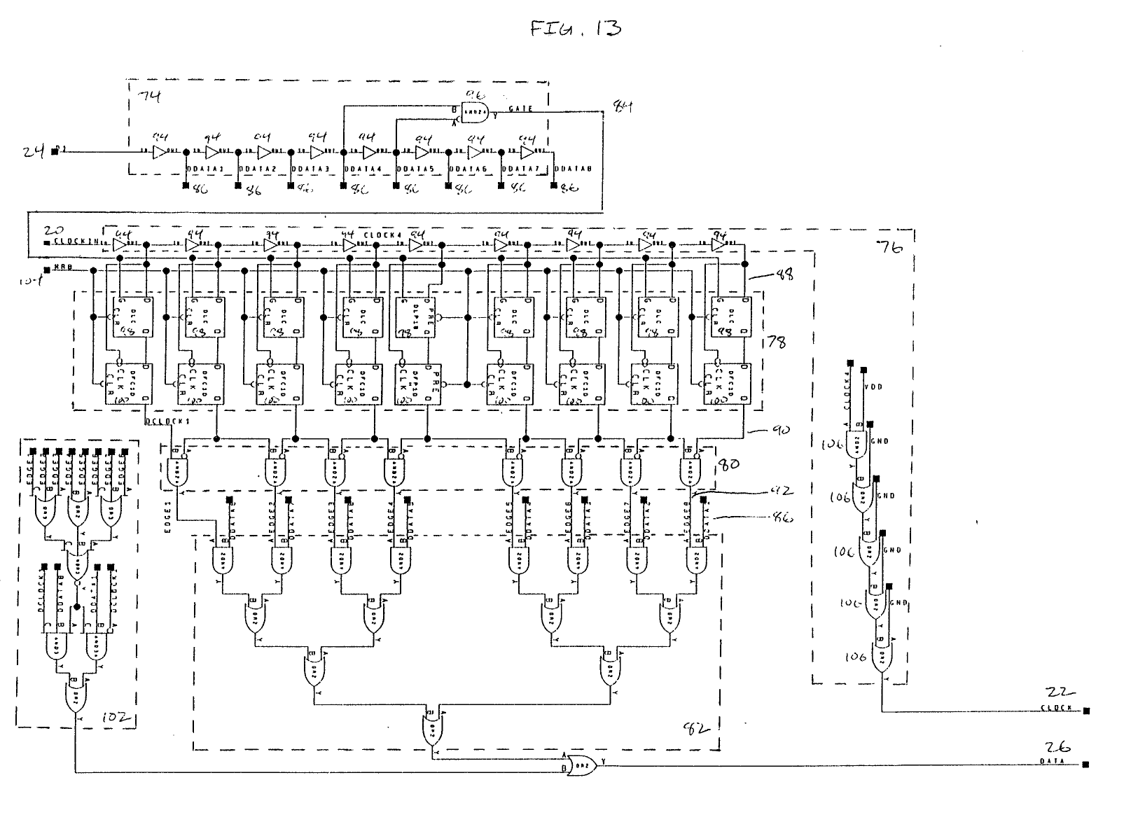

A generalized representation of a receiving system according to an alternative embodiment of the present invention is shown in FIG. 12, where receiving system 10 includes a data delay 74, a clock delay 76, a sample and hold 78, an edge finder 80, and a data selector 82. Data delay 74 receives data signal 24 and delays it by successive incremental amounts, each incremental delay within data delay 74 being output as a part of parallel data delay information 86. Clock delay 76 receives clock signal 20 and delays it by successive incremental amounts, each incremental delay within clock delay 76 being output as a part of parallel clock delay information 88. Clock delay 76 also produces delayed clock signal 22.

When a particular edge of data signal 24 propagates a certain amount (by design) through data delay 74, a gate signal 84 is produced. Gate signal 84 is received by sample and hold 78 and causes it to capture and retain the state of parallel clock delay information 88 at that point in time, which may reflect the presence of an edge of clock signal 20 propagating through clock delay 76. The captured parallel clock delay information is output as sampled clock delay information 90. Edge finder 80 receives sampled clock delay information 90 and determines how far the edge of clock signal 20 had propagated within clock delay 76, if at all, when it was captured by sample and hold 78. This information is output as delay select information 92. Because it is known by design how far data signal 24 propagates through data delay 74 when gate signal 84 is produced, if edge finder 80 can determine how far clock signal 20 had propagated through clock delay 76 at the time gate signal 84 was produced, the phase relationship between data signal 24 and clock signal 20 is known.

Data selector 82 receives parallel data delay information 86 and, based on delay select information 92, selects one of the incremental data delays comprising parallel data delay information 86 and outputs it as delayed data signal 26. The particular incremental data delay selected by data selector 82 helps to align the phase of delayed data and clock signals 26 and 22.

FIG. 13 is logic diagram representation of an embodiment of the system environment shown in FIG. 12. In the embodiment of FIG. 13, data delay 74 is comprised of delay elements 94. Gate detect element 96 is coupled across one delay element, preferably near the middle of data delay 74, and generates gate signal 84 when a data transition is sensed across the one delay element.

Clock delay 76 is preferably comprised of delay elements 94 matched as closely as possible in design and fabrication with the delay elements within data delay 74. Clock delay 76 also includes module delay elements 106 for matching the gate delays in data selector 82. Sample and hold 78 includes sampling elements 98 such as latches for asynchronously retaining the state of clock delay 76 when a gate signal 84 is received. Sample and hold 78 also includes memory elements 100 such as flip flops for synchronously holding the state of parallel clock delay information 88 when particular edges of the incrementally delayed clock signal are received.

Edge finder 80 determines when two successive memory elements 100 are at opposite states. This condition is an indication that a clock edge was captured between those two memory elements and provides a measure of the phase relationship between data signal 24 and clock signal 20. In the embodiment of FIG. 13, edge finder 80 produces a logic “1” on a particular output of delay select information 92, which is used by data selector 82 to enable a particular output of parallel data delay information 86 to be passed through to delayed data signal 26.

It should be noted in the embodiment of FIG. 13, that one of the sampling elements 98 and its corresponding memory element 100 is preset to a logic “1” to initially select the particular output of parallel data delay information 86 that corresponds to the placement of gate detect element 96 within data delay 74. However, it should also be noted that, during the course of operation, it is possible that no clock transition may be captured by sample and hold 78 when gate signal 84 is received. In that case, all outputs of delay select information 92 would be zero. Nevertheless, a path must be provided for one output of parallel data delay information 86 to pass through to delayed data signal 26. In such a situation, flat clock data delay selector 102 passes the most delayed output of parallel data delay information 86 through to delayed data signal 26 if the captured clock state of all outputs of sampled clock delay information 90 is a logic “1”, or passes the least delayed output of parallel data delay information 86 through to delayed data signal 26 if the captured clock state of all outputs of sampled clock delay information 90 is a logic “0”.

FIGS. 4, 5, 9, 10, and 13 illustrate a reset signal 104 for resetting or presetting all memory elements to a known state upon system power-up. In addition, although not shown in any figures, in alternative embodiments of the present invention, a disable input may be added to selectively disable the phase correction function of receiving system 10.

Therefore, according to the foregoing description, preferred embodiments of the present invention provide a system and process for aligning transmitted data and clock signals to minimize clock skew and data transmission errors without changing the frequency of the clock signal and without the need for an additional frequency source. Embodiments of the present invention also provide a system and process for aligning transmitted data and clock signals that can self-correct to compensate for SEUs in the receiving system.

The foregoing description of preferred embodiments of the invention has been presented for the purposes of illustration and description. It is not intended to be exhaustive or to limit the invention to the precise form disclosed. It is to be understood, therefore, that logic implementations other than those illustrated and discussed above, well understood by those skilled in the art, can be used without departing from the scope of the present invention. It is intended that the scope of the invention be limited not by this detailed description, but rather by the claims appended hereto.

What is claimed is:

1. A receiving system for aligning at least one first signal to a reference signal, the receiving system comprising:
a selectable delay for receiving at least one first signal and delaying the at least one first signal by a selectable amount to generate at least one delayed first signal;
a phase detector for receiving the at least one delayed first signal and a reference signal and generating phase information representing a phase difference between the at least one delayed first signal and the reference signal; and
a phase accumulator for receiving and accumulating the phase information and generating delay select information representing an accumulated phase difference between the at least one delayed first signal and the reference signal;
wherein the selectable delay receives the delay select information and delays the at least one first signal based on the delay select information.

2. A receiving system as recited in claim 1, further including a second delay for receiving a second signal and delaying the second signal delayed by a fixed amount to generate the reference signal.

3. A receiving system as recited in claim 1, the phase detector comprising:
a signal sampler for receiving the reference signal and the at least one delayed first signal and sampling the at least one delayed first signal at particular transitions of the reference signal to generate sampled signal information; and
an early/late detector for receiving the sampled signal information and generating phase information representing whether transitions of the at least one delayed first signal are early or late with respect to the particular transitions of the reference signal.

4. A receiving system as recited in claim 2, the selectable delay comprising:
a first incremental delay generator for receiving the at least one first signal and generating a plurality of successive first incremental delays, each successive first incremental delay representing the at least one first signal delayed by successively incremental amounts; and
a first delay selector for receiving the plurality of successive first incremental delays and the delay select information and selecting one of the successive first incremental delays based on the delay select information to generate the at least one delayed first signal.

5. A receiving system as recited in claim 4, the first delay selector comprising a first multiplexer.

6. A receiving system as recited in claim 4, the second delay comprising:
a second incremental delay generator for receiving the second signal and generating a plurality of successive second incremental delays, each successive second incremental delay representing the second signal delayed by successively incremental amounts; and
a second delay selector for receiving the plurality of successive second incremental delays and selecting one of the successive second incremental delays to generate the reference signal.

7. A receiving system as recited in claim 6, wherein the second incremental delay generator produces substantially the same delays as the first incremental delay generator, and the second delay selector produces substantially the same delays as the first delay selector.

8. A receiving system as recited in claim 6, the second delay selector comprising a second multiplexer having select inputs configured to create a delay through the second delay approximately equivalent to one half of a maximum delay achievable through the selectable delay.

9. A receiving system as recited in claim 1, the phase accumulator comprising:
an up/down counter for counting up when the phase information indicates that a transition of the at least one delayed first signal is early with respect to a particular transition of the reference signal, and for counting down when the phase information indicates that the transition of the at least one delayed first signal is late with respect to the particular transition of the reference signal, the outputs of the up/down counter comprising the delay select information; and
enable logic for enabling the up/down counter when valid phase information indicating that the transition of the at least one delayed first signal is either early or late with respect to the particular transition of the reference signal is received, except when the outputs of the up/down counter are all at a uniform state.

10. A receiving system as recited in claim 4, the phase accumulator comprising:
a shift register comprising a plurality of memory elements, each memory element initially preset to a nonasserted state except for one memory element preset to an asserted state, the shift register for shifting the asserted state right when the phase information indicates that a transition of the at least one delayed first signal is early with respect to a particular transition of the reference signal, and for shifting the asserted state left when the phase information indicates that the transition of the at least one delayed first signal is late with respect to the particular transition of the reference signal, the outputs of the shift register comprising the delay select information; and
enable logic for enabling the shift register when valid phase information indicating that the transition of the at least one delayed first signal is either early or late with respect to the particular transition of the reference signal is received, except when the asserted state is in a leftmost or rightmost memory element of the shift register.

11. A receiving system as recited in claim 10, the first delay selector comprising a combinational logic tree for selecting one of the plurality of successive first incremental delays based on the delay select information and generating the at least one delayed first signal.

12. A receiving system as recited in claim 11, wherein the second delay produces a delay approximately equivalent to one half of a maximum delay achievable through the selectable delay.

13. A receiving system for aligning a first signal to a reference signal, the receiving system comprising:
a first incremental delay generator for receiving a first signal and generating a plurality of successive first incremental delays, each successive first incremental delay representing the first signal delayed by successively incremental amounts, and for generating a gate signal which indicates when a transition on the first signal has propagated a fixed amount through the first incremental delay generator;
a reference signal incremental delay generator for receiving a second signal and generating a plurality of successive reference signal incremental delays, each successive reference signal incremental delay representing the second signal delayed by successively incremental amounts, and for generating a reference signal;
a sample and hold for receiving the plurality of successive reference signal incremental delays and generating sampled reference signal delay information representing a state of the plurality of successive reference signal incremental delays when the gate signal is received;
an edge finder for receiving the sampled reference signal delay information and generating delay select information representing a location of a transition of the second signal within the reference signal incremental delay generator, if any, when the gate signal is received; and
a first signal selector for receiving the delay select information and the plurality of successive first incremental delays and selecting one of the plurality of successive first incremental delays to be output as a delayed first signal based on the delay select information.

14. A receiving system as recited in claim 13, the sample and hold comprising:
a plurality of latches, each latch for sampling a particular one of the plurality of successive reference signal incremental delays when the gate signal is received; and
a plurality of memory elements, each memory element coupled to a particular one of the plurality of latches for holding the state of the latches when a particular transition of the particular one of the plurality of successive reference signal incremental delays coupled to the particular one of the plurality of latches is received.

15. A receiving system as recited in claim 14, wherein all latch and memory element pairs within the sample and hold are initially preset to a nonasserted state except for one pair which is preset to an asserted state, the asserted pair for initially selecting one of the plurality of successive first incremental delays to be output as the delayed first signal.

16. A receiving system as recited in claim 14, the edge finder comprising a plurality of logic elements, each logic element coupled to a particular pair of successive ones of the plurality of memory elements for detecting when the particular pair of memory elements are at different states.

17. A receiving system as recited in claim 13, further including a flat clock data delay selector for selecting one of the plurality of successive first incremental delays to be output as the delayed first signal when no transition of the second signal within the reference signal incremental delay generator is detected by the edge finder.

18. A process for aligning at least one first signal to a reference signal, the process comprising:
detecting a phase difference between at least one delayed first signal and a reference signal to generate phase information;
accumulating the phase information and generating delay select information representing an accumulated phase difference between the at least one delayed first signal and the reference signal; and
adjustably delaying at least one first signal based on the delay select information to generate the at least one delayed first signal.

19. A process as recited in claim 18, further including the step of delaying a second signal by a fixed amount to generate the reference signal.

20. A process for aligning a first signal to a reference signal, the process comprising:
receiving a first signal and generating a plurality of successive first incremental delays, each successive first incremental delay representing the first signal delayed by successively incremental amounts;
generating a gate signal when a transition on the first signal appears within the plurality of successive first incremental delays;
receiving a second signal and generating a plurality of successive reference signal incremental delays and a reference signal, each successive reference signal incremental delay representing the second signal delayed by successively incremental amounts;
sampling and holding a state of the plurality of successive reference signal incremental delays when the gate signal is received;
locating a transition of the second signal, if any, from the sampled and held states of the plurality of successive reference signal incremental delays; and
selecting one of the plurality of successive first incremental delays to be output as a delayed first signal based on the located transition of the second signal.
